(19) United States
(12) Patent Application Publication
(10) Pub. No.: US 2021/0184428 A1
(43) Pub. Date: Jun. 17, 2021

(54) SEMICONDUCTOR LASER ELEMENT

(71) Applicant: Sharp Fukuyama Laser Co., Ltd., Fukuyama City (JP)

(72) Inventors: AKINORI NOGUCHI, Fukuyama City (JP); YOSHIHIKO TANI, Fukuyama City (JP); YUHZOH TSUDA, Fukuyama City (JP)

(21) Appl. No.: 17/119,130

(22) Filed: Dec. 11, 2020

(30) Foreign Application Priority Data
Dec. 12, 2019 (JP) 2019-224740

(51) Int. Cl. H01S 5/10; H01S 5/343; H01S 5/042; H01S 5/22

(52) U.S. Cl. CPC H01S 5/1021; H01S 5/34333; H01S 5/34346; H01S 5/22; H01S 5/04256

(57) ABSTRACT

A semiconductor laser element configured to emit laser light, the semiconductor laser element comprises a substrate; and a semiconductor layer provided on the substrate, wherein the semiconductor layer includes a waveguide extending in a predetermined direction and configured to emit the laser light from one end face of the waveguide, the substrate includes a plurality of cavity sections intersecting the predetermined direction and extending, the plurality of cavity sections are provided in the substrate such that at least parts of at least two cavity sections of the plurality of cavity sections overlap with each other along the predetermined direction, and a length of each of the plurality of cavity sections in a direction perpendicular to the predetermined direction is shorter than a length of the semiconductor laser element in the perpendicular direction.

### CROSS-REFERENCE TO RELATED APPLICATION

The present application claims priority from Japanese Application JP2019-224740, the content of which is hereby incorporated by reference into this application.

### BACKGROUND OF THE INVENTION

### 1. Field of the Invention

One aspect of the disclosure relates to a semiconductor laser element.

### 2. Description of the Related Art

In recent years, the use of blue laser light or green laser light emitted from a nitride-based semiconductor has been attracting attention for next generation applications such as directional lights, projectors, or televisions. Since the visibility of laser light is required in these applications, high radiation quality of the laser light is required. However, since a substrate for a normal nitride-based semiconductor is transparent, stray light from an active layer leaks from the substrate.

A semiconductor laser element 500 disclosed in JP 2018-195749 A, for example, is provided as a semiconductor laser element in which stray light leaking from a substrate is reduced. FIG. 24 is a perspective view of the semiconductor laser element 500 of JP 2018-195749 A. As illustrated in FIG. 24, in the semiconductor laser element 500 disclosed in JP 2018-195749 A, a semiconductor layered film 510 is layered on an upper surface of a substrate 502, and a waveguide 531 is formed by the semiconductor layered film 510. Further, grooves 543 extending in a direction intersecting the waveguide 531 are provided in a lower surface of the substrate 502, and this can reduce stray light leaking from the substrate 502.

### SUMMARY OF THE INVENTION

One aspect of the disclosure is to reduce stray light leaking from a substrate and reduce the possibility of element cracking of a semiconductor laser element.

To solve the above problem, a semiconductor laser element according to one aspect of the disclosure is a semiconductor laser element configured to emit laser light and includes a substrate and a semiconductor layer provided on the substrate. The semiconductor layer includes a waveguide extending in a predetermined direction and configured to emit the laser light from one end face of the waveguide, the substrate includes a plurality of cavity sections intersecting the predetermined direction and extending, the plurality of cavity sections are provided in the substrate such that at least parts of at least two cavity sections of the plurality of cavity sections overlap with each other along the predetermined direction, and a length of each of the plurality of cavity sections in a direction perpendicular to the predetermined direction is shorter than a length of the semiconductor laser element in the perpendicular direction.

According to one aspect of the disclosure, the stray light leaking from the substrate can be reduced, and the possibility of the element cracking of the semiconductor laser element can be reduced.

### BRIEF DESCRIPTION OF THE DRAWINGS

FIG. 1 is a perspective view illustrating a configuration of a semiconductor laser element according to a first embodiment of the disclosure.

FIG. 2 is a front view illustrating a layered structure of an active layer of the semiconductor laser element according to the first embodiment of the disclosure.

FIG. 3 is a schematic cross-sectional view when a cavity section of the semiconductor laser element according to the first embodiment of the disclosure is cut along a plane perpendicular to a bottom surface of the semiconductor laser element in a Y direction.

In FIG. 4, a reference numeral 401 indicates a top view of the semiconductor laser element according to the first embodiment of the disclosure, and a reference numeral 402 indicates a diagram illustrating another example of the cavity section.

FIG. 5 is a schematic perspective view illustrating a structure of a plurality of cavity sections of the semiconductor laser element according to the first embodiment of the disclosure.

FIG. 6 is a schematic front view illustrating a structure when the cavity section of the semiconductor laser element according to the first embodiment of the disclosure is viewed from an emission surface.

FIG. 7 is a flowchart illustrating an example of a manufacturing process of the semiconductor laser element according to the first embodiment of the disclosure.

FIG. 8 is a bottom view illustrating a chip dividing groove forming step in a wafer according to the first embodiment of the disclosure.

FIG. 9 is a bottom view illustrating a cavity section forming step in the wafer according to the first embodiment of the disclosure.

FIG. 10 is a top view illustrating a bar dividing groove forming step in the wafer according to the first embodiment of the disclosure.

FIG. 11 is a perspective view illustrating an end face coating film forming step in a bar according to the first embodiment of the disclosure.

FIG. 12 is a diagram illustrating a forming pattern of cavity sections of a semiconductor laser element according to a second embodiment of the disclosure.

FIG. 13 is a diagram illustrating a forming pattern of cavity sections of a semiconductor laser element according to a third embodiment of the disclosure.

FIG. 14 is a diagram illustrating a forming pattern of cavity sections of a semiconductor laser element according to a fourth embodiment of the disclosure.

FIG. 15 is a diagram illustrating a forming pattern of cavity sections of a semiconductor laser element according to a fifth embodiment of the disclosure.

FIG. 16 is a diagram illustrating a forming pattern of cavity sections of a semiconductor laser element according to a sixth embodiment of the disclosure.

FIG. 17 is a diagram illustrating a forming pattern of cavity sections of a semiconductor laser element according to a seventh embodiment of the disclosure.

FIG. 18 is a diagram illustrating a forming pattern of cavity sections of a semiconductor laser element according to an eighth embodiment of the disclosure.

FIG. 19 is a diagram illustrating a forming pattern of cavity sections of a semiconductor laser element according to a ninth embodiment of the disclosure.

FIG. 20 is a diagram illustrating test results for comparative examples.

FIG. 21 is a diagram illustrating test results for semiconductor laser elements according to one aspect of the disclosure.

FIG. 22 is a schematic front view illustrating a structure of a cavity section of a semiconductor laser element according to a tenth embodiment of the disclosure when viewed from an emission surface.

FIG. 23 is a schematic perspective view illustrating a structure of a plurality of cavity sections of the semiconductor laser element according to the tenth embodiment of the disclosure.

FIG. 24 is a perspective view of a semiconductor laser element of JP 2018-195749 A.

### DETAILED DESCRIPTION OF THE INVENTION

### First Embodiment

An embodiment of the disclosure will be described in detail below.

### Configuration of Nitride Semiconductor Laser Element

A case in which a semiconductor laser element 100 is a nitride semiconductor laser element is described herein as an example.

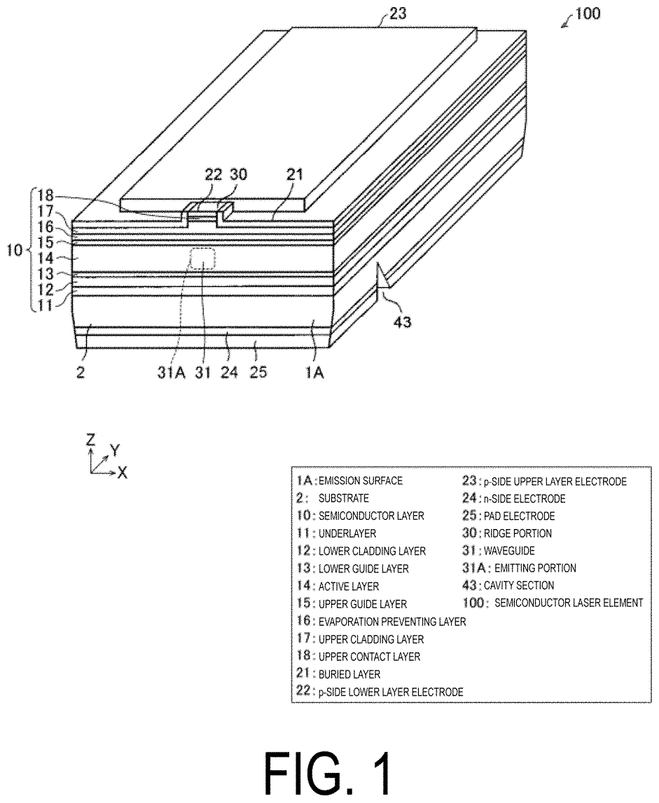

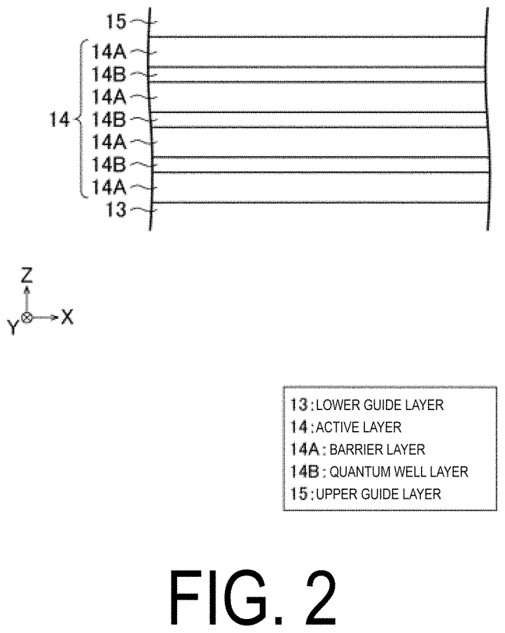

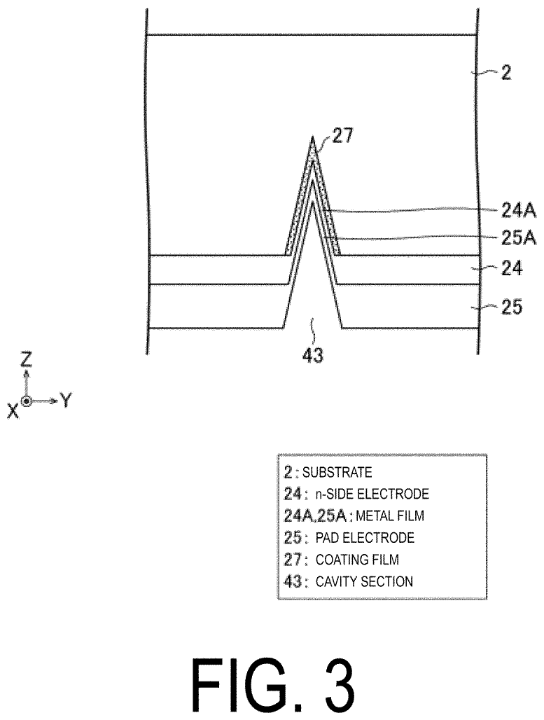

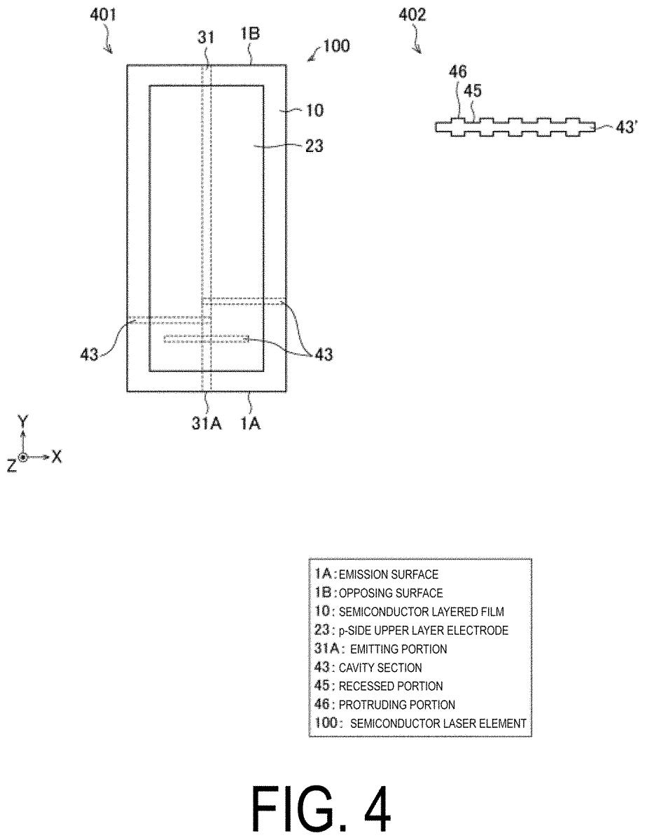

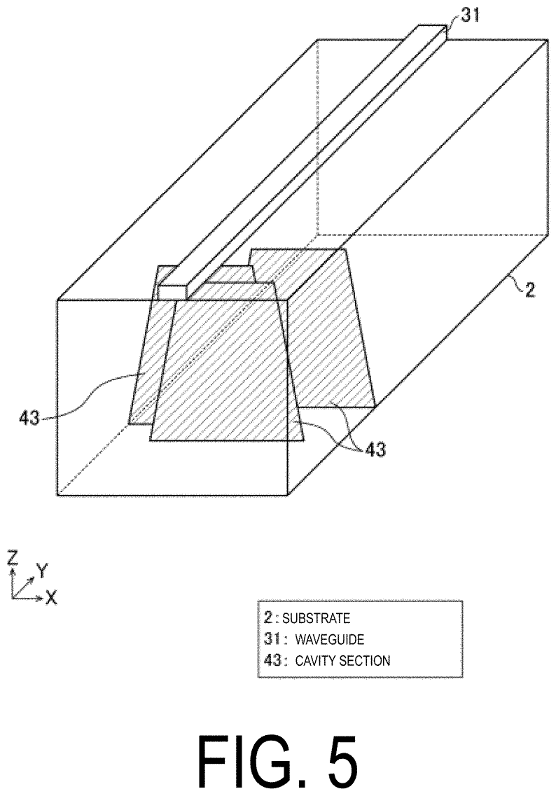

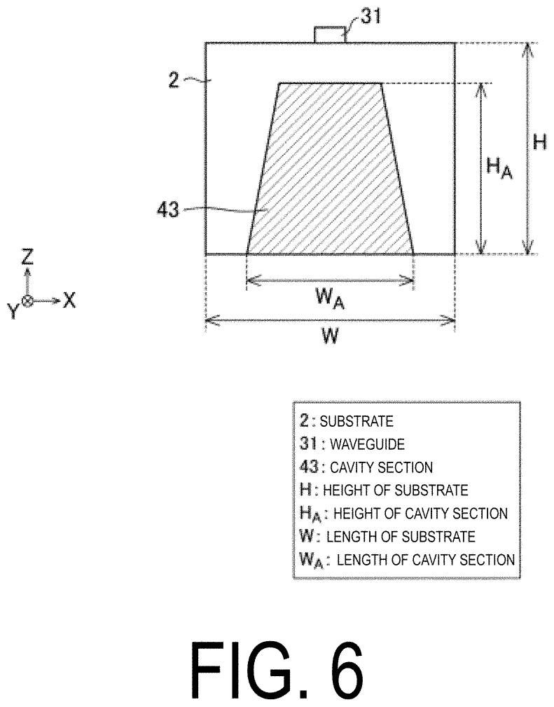

FIG. 1 is a perspective view illustrating a configuration of the semiconductor laser element 100 according to a first embodiment. FIG. 2 is a front view illustrating a layered structure of an active layer 14 of the semiconductor laser element 100 according to the first embodiment. FIG. 3 is a schematic cross-sectional view when a cavity section 43 of the semiconductor laser element 100 according to the first embodiment is cut along a plane perpendicular to a bottom surface of the semiconductor laser element 100 in a Y direction. A reference numeral 401 in FIG. 4 indicates a top view of the semiconductor laser element 100 according to the first embodiment. A reference numeral 402 in FIG. 4 indicates a cavity section 43′, in a case in which a recessed and protruding portion is provided on a side surface of the cavity section 43 of the semiconductor laser element indicated by the reference numeral 401 in FIG. 4. FIG. 5 is a schematic perspective view illustrating a structure of a plurality of cavity sections 43 of the semiconductor laser element 100 according to the first embodiment. FIG. 6 is a schematic front view illustrating a structure when the cavity section 43 of the semiconductor laser element 100 according to the first embodiment is viewed from an emission surface 1A.

Note that FIG. 1 is a diagram schematically illustrating the configuration of the semiconductor laser element 100 according to the present embodiment, and does not limit the number of each member constituting the semiconductor laser element 100 and the dimensions of the members. Additionally, in coordinate axes illustrated in FIG. 1, a Z axis positive direction side is defined as “upper”, and a surface of each member on the positive Z direction side is referred to as an “upper surface”. This also applies to other drawings. “A to B” used herein indicates “A or greater and B or less”.

As illustrated in FIG. 1, the semiconductor laser element 100 includes a substrate 2, a semiconductor layer 10, a buried layer 21, a p-side lower layer electrode 22, a p-side upper layer electrode 23, and a ridge portion 30. As illustrated in FIG. 1, the semiconductor laser element 100 further includes an n-side electrode 24 on a lower side surface of the substrate 2, and a pad electrode 25 on a lower side surface of the n-side electrode 24.

In a case where voltage is applied between the p-side upper layer electrode 23 and the n-side electrode 24, the semiconductor layer 10 emits laser light. The semiconductor layer 10 is a semiconductor layered structure that is epitaxially grown on an upper surface of the substrate 2. The semiconductor layer 10 includes an underlayer 11, a lower cladding layer 12, a lower guide layer 13, an active layer 14, an upper guide layer 15, an evaporation preventing layer 16, an upper cladding layer 17, and an upper contact layer 18 in this order from the substrate 2.

The substrate 2 is a conductive nitride semiconductor substrate, and is made of, for example, GaN.

The underlayer 11 is a layer provided to reduce stress or scratches received on the substrate 2 when the substrate 2 is surface-processed. In a case where the underlayer 11 is layered on the substrate 2, the surface of the substrate 2 can be flattened. The underlayer 11 is a layer that facilitates application of current or voltage from the n-side electrode 24 to the active layer 14. The underlayer 11 is a layer formed of n-type GaN and has a film thickness from 0.1 to 10 μm (for example, 4 μm).

The lower cladding layer 12 is a layer that confines current and light generated in the active layer 14. The lower cladding layer 12 is formed of n-type Al₁Ga₁₋ₓ₁N (0<x1<1) and has a film thickness from 0.5 to 3.0 μm (for example, 2 μm).

The lower guide layer 13 is a layer that facilitates propagation of light in the active layer 14. The lower guide layer 13 is formed of Inₓ₄Ga₁₋₄ₓN (0≤x2<0.1) and has a film thickness of 0.3 μm or less (for example, 0.1 μm). An n-type lower guide layer 13 in which Si or the like is doped is also possible.

The active layer 14 is an active portion that has optical amplification action by stimulated emission. As illustrated in FIG. 2, the active layer 14 has a multi quantum well (MQW) structure in which, for example, four barrier layers 14A and three quantum well layers 14B are alternately layered. The quantum well layer 14B is formed of, for example, Inₓ₃Ga₁₋ₓ₃N having a film thickness of 4 nm. The barrier layer 14A is formed of, for example, Inₓ₄Ga₁₋₄ₓN (where x3>x4) having a film thickness of 8 nm. x3 and x4 can be x3=0.05 to 0.35 and x4=0 to 0.1, for example.

The upper guide layer 15 is a layer that facilitates propagation of light in the active layer 14. The upper guide layer 15 is formed of In_{y2}Ga_{1-y2}N (0≤y2<0.1) and has a film thickness of 0.3 μm or less (for example, 0.1 μm). A p-type upper guide layer 15 in which Mg or the like is doped is also possible.

The evaporation preventing layer 16 is a layer that prevents In in a nitride semiconductor containing In from evaporating. The evaporation preventing layer 16 is a layer formed of p-type Al_{y1}Ga_{1-y1}N (0<y1<1) and has a film thickness of 0.02 μm or less (for example 0.01 μm).

The upper cladding layer 17 is a layer that confines current and light generated in the active layer 14. The upper cladding layer 17 is a layer formed of p-type Al_{y3}Ga_{1-y3}N (0<y3<1). The upper cladding layer 17 has a film thickness from 0.01 to 1 μm (for example, 0.5 μm).

The ridge portion 30 limits an area in which current flows along the Y direction and causes laser oscillation in an area of the active layer 14 corresponding to the area. The area where the laser oscillation occurs in the active layer 14 functions as a waveguide 31. For example, a protruding portion formed by etching a part of the upper cladding layer 17 to an intermediate position in a thickness direction (Z direction) by a photolithography technique functions as the ridge portion 30. As illustrated in FIG. 1, the ridge portion 30 is formed so as to extend in the Y direction. Note that a method for forming the ridge portion 30 is described in more detail in the following manufacturing method.

The upper contact layer 18 is a layer that facilitates application of current or voltage to the active layer 14. The upper contact layer 18 is provided on the protruding portion of the upper cladding layer 17 that forms the ridge portion 30. The upper contact layer is formed of p-type GaN and has a film thickness from 0.01 to 1 μm (for example, 0.05 μm).

The buried layer 21 is a layer that functions as a current constriction layer. The buried layer 21 is formed of an insulating material such as SiO₂ and has a film thickness from 0.1 to 0.3 μm (for example, 0.15 μm). As illustrated in FIG. 1, light may be confined in the ridge portion 30 in an operation mode by covering both side surfaces of the ridge portion 30 with the buried layer 21.

The p-side lower layer electrode 22 is a conductive layer having Pd or Ni as a main component. The p-side lower layer electrode 22 is in ohmic contact with the upper contact layer 18.

The p-side upper layer electrode 23 is an electrode for injecting a carrier from the upper surface of the ridge portion 30. The p-side upper layer electrode 23 is formed on the upper surface of the ridge portion 30 (on the upper contact layer 18 and the buried layer 21 of the ridge portion 30). The p-side upper layer electrode 23 is an example of a metal layer formed of Au, for example.

The n-side electrode 24 is an electrode for injecting a carrier from below the substrate 2. The n-side electrode 24 is in ohmic contact with the substrate 2. The n-side electrode 24 is formed, for example, of a single layer of Ti or a Ti/Al multilayer body in which Ti is layered and Al is further layered thereon.

The pad electrode 25 is a layer for easily connecting and fixing the semiconductor laser element 100 to a submount or the like. The pad electrode 25 is formed of, for example, Au.

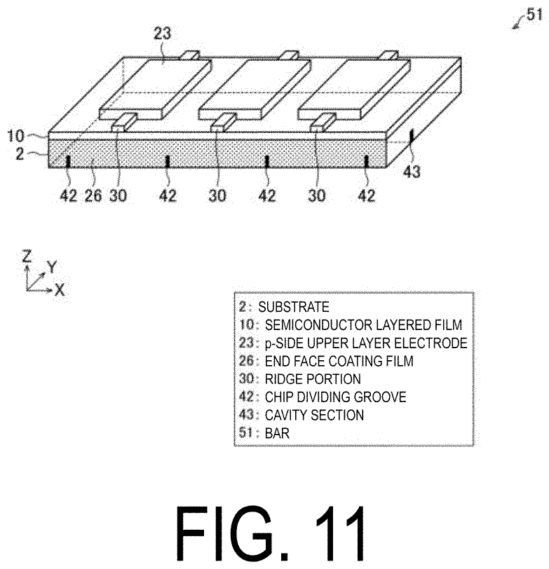

Additionally, an end face coating film 26 (see FIG. 11; the end face coating film 26 of FIG. 11 is formed so as to cover end faces of the substrate 2, end faces of the semiconductor layered film 10, and end faces of the ridge portion 30) is provided on the emission surface 1A and an opposing surface 1B (see FIG. 4) of the semiconductor laser element 100. The end face coating film 26 on the emission surface 1A is formed of a low reflective film such as Al₂O₃. The end face coating film 26 on the opposing surface 1B is formed of a highly reflective film in which Al₂O₃ and Ta₂O₅ are alternately layered (for example, nine layers). The waveguide 31 extending in the Y direction constitutes a resonator with the end face coating films 26 on the emission surface 1A and the opposing surface 1B. This allows laser light to be emitted from an emitting portion 31A, which is one end face of the waveguide 31, in a case where current is injected from the p-side upper layer electrode 23 into the active layer 14 via the ridge portion 30. In other words, the semiconductor layer 10 includes the waveguide 31 that extends in the Y direction and emits laser light from the emitting portion 31A.

Further, as illustrated in FIGS. 4 and 5, a plurality of cavity sections 43 are provided in the lower surface of the substrate 2. The substrate 2 of the semiconductor laser element 100 is usually made of a transparent material. Thus, laser light generated in the active layer 14 may not only be emitted from the emitting portion 31A, which is the one end face of the waveguide 31, but also leak from the substrate 2 as stray light. The cavity section 43 provided in the substrate 2 is configured to reduce an amount of stray light leaking from the substrate 2 by utilizing a change in a reflective index or the like. The detailed configuration and effect of the cavity section 43 will be described in detail below.

### Cavity Section

As illustrated in FIGS. 4 and 5, in the semiconductor laser element 100 according to the first embodiment, three cavity sections 43 having a groove structure are formed at different distances from the emission surface 1A. Further, the cavity sections 43 overlap with each other along the Y direction and each extend so as to intersect the waveguide 31. The cavity section 43 is formed in the lower surface of the substrate 2 by, for example, laser scribing. As illustrated in FIG. 6, the cavity section 43 has a length W_{A} in the X direction perpendicular to the Y direction and a height H_{A} in a thickness direction of the substrate of the semiconductor laser element 100 (Z direction). For the three cavity sections 43, the length W_{A} of each cavity section 43 is shorter than a length W of the semiconductor laser element 100 in the X direction.

Further, in the present embodiment, the length W_{A} of the cavity section 43 in the X direction is preferably long in order to shield stray light and reduce laser light leaking from the substrate 2. On the other hand, when the cavity section 43 reaches both ends of the semiconductor laser element 100 in the X direction, the possibility of element cracking increases. Thus, the length W_{A} of the cavity section 43 in the X direction is preferably from 30% to 80%, more preferably from 50% to 70% of the length W of the semiconductor laser element 100 in the X direction.

In the example of FIGS. 4 and 5, the three cavity sections 43 have substantially the same shape. In other words, the length W_{A} and the height H_{A} of the three cavity sections 43 are substantially the same. Specifically, each of the three cavity sections 43 extends substantially linearly when viewed from the upper surface side of the substrate 2, and has a substantially trapezoidal shape when viewed from the emission surface 1A side. In this example, in the X direction, one cavity section 43 is disposed inside the substrate 2 (for example, substantially in a center) and one end portions of two cavity sections 43 are exposed on the side surface of the substrate 2. Specifically, one end portion of one cavity section 43 of the two cavity sections 43 is in contact with one side surface of the substrate 2 (exposed on the side surface), and one end portion of another cavity section 43 is in contact with another side surface of the substrate 2. In other words, at least one end portion of each of the three cavity sections 43 is not in contact with the side surface of the substrate 2. Additionally, the three cavity sections 43 are disposed at different distances from the emission surface 1A, and at least parts of the three cavity sections 43 overlap with each other across the entire X direction of the substrate 2 in the Y direction when viewed from the emission surface 1A side. In this example, the cavity section 43 disposed inside in the X direction and each of the two other cavity sections 43 overlap with each other in the Y direction.

Note that FIG. 5 is a schematic view for illustrating an arrangement of a plurality of cavity sections 43, and a width (length in the Y direction) of the cavity section 43 is ignored in the drawing. The width of the cavity section 43 is not particularly limited to a specific width, but any width of the cavity section 43 can be obtained by changing a frequency and a sweeping velocity of laser when the cavity section 43 is formed by laser scribing.

Note that the number of cavity sections 43 provided in the semiconductor laser element 100 is not limited to three, and may be two or more. Further, it is not always necessary that all the plurality of cavity sections 43 overlap with each other along the Y direction. It is sufficient that at least two cavity sections 43 overlap, and at least parts of the two cavity sections 43 may overlap. In addition, the cavity section 43 may extend in a direction not orthogonal to the waveguide 31 as long as the cavity section 43 extends in a direction intersecting the waveguide 31, or need not extend intersecting the waveguide 31. Further, in the first embodiment, as illustrated in FIG. 3, the cavity section 43 is illustrated in a shape of a groove including an opening on the lower surface of the substrate 2. However, the shape of the cavity section 43 is not limited to the shape of the groove, and the cavity section having a light-shielding function may be formed in a direction intersecting the waveguide 31. In other words, it is not always necessary that all the cavity sections 43 be implemented as grooves. Furthermore, the plurality of cavity sections 43 need not have the same shape as each other, and do not necessarily have the shape illustrated in FIGS. 4 and 5 and are not necessarily formed with the arrangement pattern illustrated in FIGS. 4 and 5. Examples of a plurality of cavity sections having shapes different from that of the first embodiment, and examples of a plurality of cavity sections formed with arrangement patterns different from that of the first embodiment will be described in other embodiments described below.

### Method for Manufacturing Semiconductor Laser Element 100

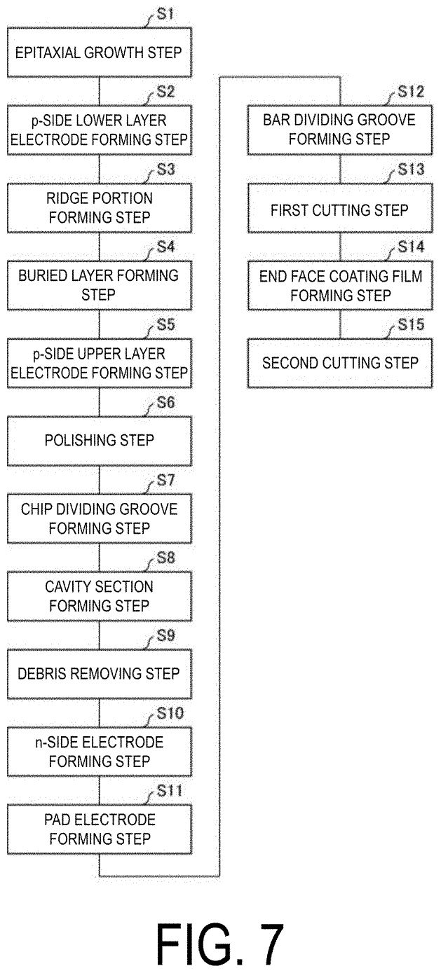

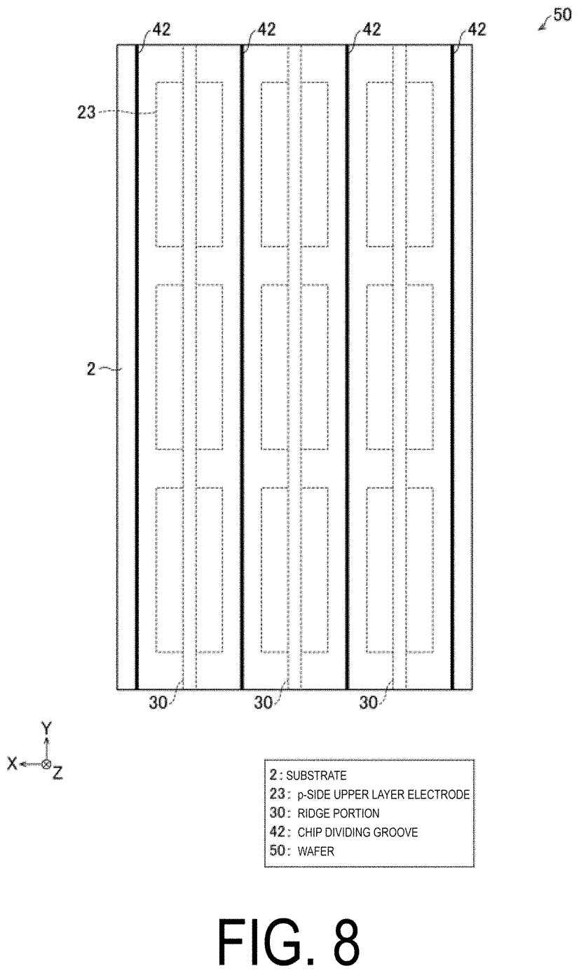

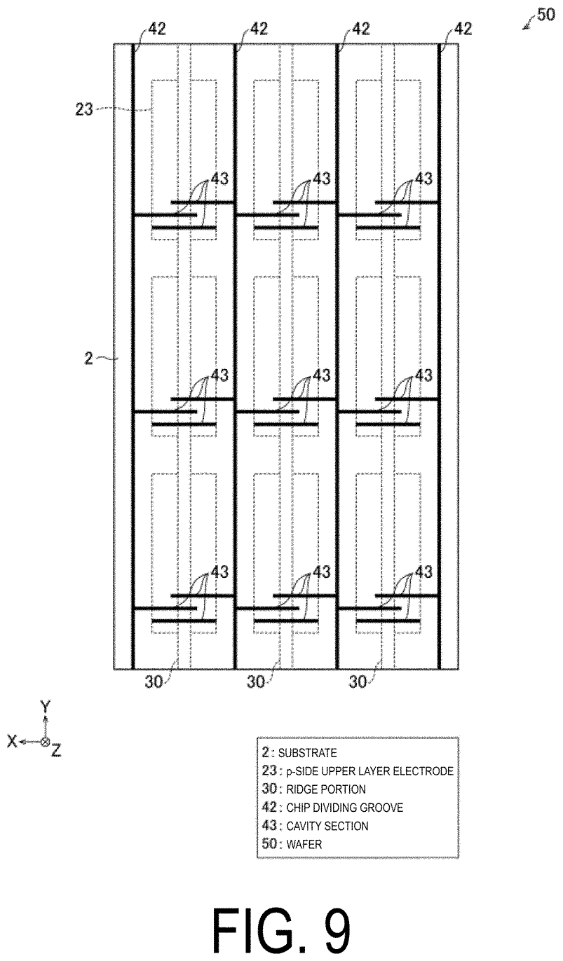

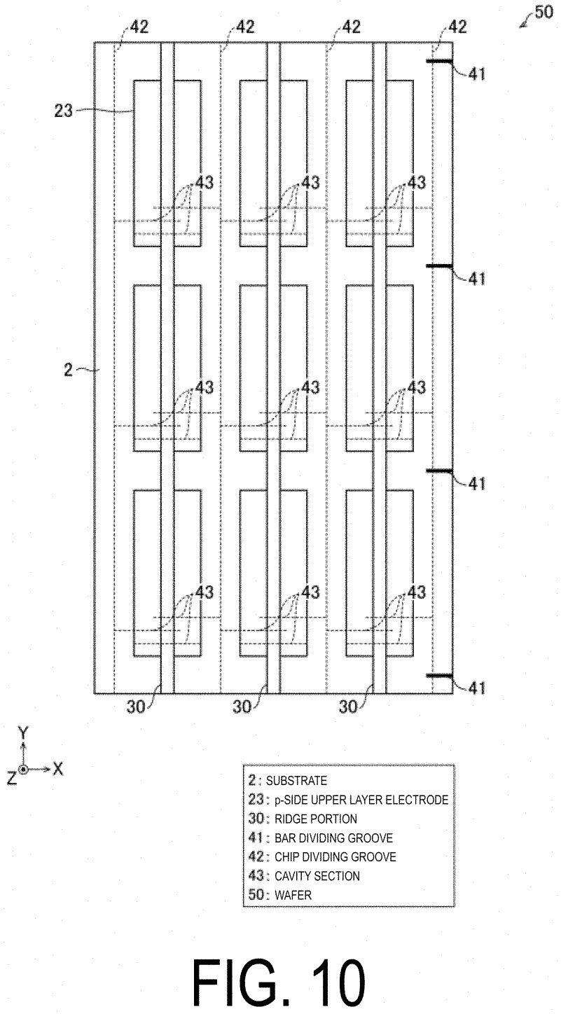

Hereinafter, a manufacturing process of the semiconductor laser element 100 according to the present embodiment will be described with reference to FIGS. 7 to 11. In the following description, a wafer-shaped intermediate in the middle of the process may be simply referred to as a wafer 50. Also, a bar-shaped intermediate obtained by dividing the wafer 50 in the middle of the process may be simply referred to as a bar 51. FIG. 7 is a flowchart illustrating an example of a manufacturing process of the semiconductor laser element 100 according to the present embodiment. FIG. 8 is a bottom view illustrating a step of forming a chip dividing groove 42 in the wafer 50 according to the present embodiment. FIG. 9 is a bottom view illustrating a step of forming the cavity section 43 in the wafer 50 according to the present embodiment. FIG. 10 is a top view illustrating a step of forming a bar dividing groove 41 in the wafer 50 according to the present embodiment. FIG. 11 is a perspective view illustrating a step of forming the end face coating film 26 in the bar 51 according to the present embodiment.

As illustrated in FIG. 7, a method for manufacturing the semiconductor laser element 100 according to the present embodiment includes steps S1 to S15. In the present embodiment, the semiconductor laser element 100 is manufactured in this order as an example. However, the present embodiment is not limited to the manufacturing steps described above as long as the semiconductor laser element 100 having the layered structure illustrated in FIG. 1 can be manufactured. The above steps will be described below.

In step S1 illustrated in FIG. 7, the semiconductor layer 10 is epitaxially grown on the upper surface of the substrate 2 (epitaxial growth step). The epitaxial growth is performed by, for example, a metal organic chemical vapor deposition (MOCVD) method or the like.

In other words, the underlayer 11, the lower cladding layer 12, and the lower guide layer 13 are sequentially grown on the upper surface of the substrate 2. Next, the four barrier layers 14A and the three quantum well layers 14B (see FIG. 3) are alternately grown on the upper surface of the lower guide layer 13 to obtain the active layer 14. Subsequently, the upper guide layer 15, the evaporation preventing layer 16, the upper cladding layer 17, and the upper contact layer 18 are sequentially grown on the active layer 14.

When forming the semiconductor layer 10 using the MOCVD method, trimethylgallium, ammonia, trimethylaluminum, trimethylindium, silane, or bis-cyclopentadienyl magnesium can be used as a raw material. Further, hydrogen or nitrogen can be used as a carrier gas.

Subsequently, in step S2, the p-side lower layer electrode 22 is formed on the upper contact layer 18 of the wafer 50 by vacuum vapor deposition, sputtering, or the like (p-side lower layer electrode forming step).

Subsequently, in step S3, the ridge portion 30 is formed (ridge portion forming step). Specifically, a resist (not illustrated) is formed by photolithography in an area where the ridge portion 30 on the p-side lower layer electrode 22 of the wafer 50 is to be formed. The resist is formed in a band shape extending in the Y direction. Next, reactive ion etching (RIE) is performed using SiCl₄ gas, Cl₂ gas, Ar gas, or the like to etch a portion where the resist is not formed. As a result, the ridge portion 30 including the protruding portion at the upper end portion of the upper cladding layer 17, the upper contact layer 18, and the p-side lower layer electrode 22 is formed. By forming the ridge portion 30, the waveguide 31 (see FIG. 1) extending in the Y direction is obtained below the ridge portion 30.

Note that etching in the ridge portion forming step may be performed by dry etching such as the above RIE or wet etching.

Alternatively, a mask layer of, for example, SiO₂ may be provided in the forming area of the ridge portion 30 instead of the resist. In this case, a resist is provided in an area where the ridge portion 30 is not formed by photolithography, and after film formation of SiO₂, the resist and SiO₂ on the resist are removed to form a mask layer. The mask layer can be removed using, for example, an etchant such as buffered hydrogen fluoride (BHF).

Subsequently, in step S4, the buried layer 21 made of SiO₂ or the like is formed on the upper surface of the resist, both side walls of the ridge portion 30, and the upper cladding layer 17 by sputtering or the like. Thereafter, the buried layer 21 on the resist is removed together with the resist, and the p-side lower layer electrode 22 is exposed (buried layer forming step).

Subsequently, in step S5, the p-side upper layer electrode 23 is formed on the upper surface of the p-side lower layer electrode 22 disposed on the ridge portion 30 and the buried layer 21 by vacuum vapor deposition, sputtering, or the like (p-side upper layer electrode forming step). Note that, as illustrated in FIG. 8, a plurality of p-side upper layer electrodes 23 are provided in a patterned manner according to the layout of the semiconductor laser element 100 to be formed in a chip shape by dividing the wafer 50.

Subsequently, in step S6, the lower surface of the substrate 2 is polished so that a thickness of the substrate 2 is from 80 to 150 μm (for example 130 μm) (polishing step). This allows the wafer 50 and the bar 51 (see FIG. 11) to be easily divided in a first cutting step and a second cutting step described below. Note that the substrate 2 may be physically polished with an abrasive or may be chemically polished with a chemical.

Subsequently, in step S7, a plurality of chip dividing grooves 42 are formed in the lower surface of the substrate 2 of the wafer 50 by, for example, laser scribing (chip dividing groove forming step) (see FIG. 8). The chip dividing groove 42 extends in the Y direction and is disposed between the ridge portions 30.

After dividing the wafer 50 into a plurality of bars 51 in the first cutting step described below, the chip dividing groove 42 is used to dice the bars 51 into chips in the second cutting step. Therefore, the chip dividing groove 42 is disposed at a position based on the ridge portion 30, such as a center between the ridge portions 30, for example. This allows desired chips to be obtained with a good yield when the bar 51 is divided into the chips.

The chip dividing groove 42 is more preferably formed at a depth from approximately 5 to 60 μm from the lower surface of the substrate 2. This makes it possible to remove the possibility in that the bar cannot be divided into chips because the chip dividing groove 42 is too shallow, or to prevent the wafer 50 from being damaged during handling because the chip dividing groove 42 is too deep. Additionally, the chip dividing groove 42 is formed in a straight line extending between both end faces of the wafer 50 in the Y direction. This can reduce the possibility in that when dividing the bar 51 into the chip shaped semiconductor laser elements 100, the bar 51 cracks in an unintended direction.

Subsequently, in step S8, a plurality of cavity sections 43 are formed in the lower surface of the substrate 2 of the wafer 50 by, for example, laser scribing (cavity section forming step) (see FIG. 9). The cavity sections 43 extend so as to intersect the ridge portion 30, and are provided in plurality corresponding to the respective semiconductor laser elements 100 that are to be diced into chips. Further, the plurality of cavity sections 43 are provided so as to overlap with each other in the Y direction in each semiconductor laser element 100. As described above, the plurality of cavity sections 43 need not intersect the ridge portion 30, and may be provided so as to intersect the Y direction. Further, it is sufficient that at least parts of at least two cavity sections 43 of the plurality of cavity sections 43 may be provided so as to overlap with each other in the Y direction.

In the semiconductor laser element 100, in a case where the height H_{A} of the cavity section 43 is one tenth or greater of the thickness H of the substrate 2, approximately 10% of stray light can be shielded. Further, in a case where the height H_{A} of the cavity section 43 is one third or greater of the thickness H of the substrate 2, 30% or greater of stray light can be shielded. On the other hand, in a case where the height H_{A} of the cavity section 43 is greater than the thickness H of the substrate 2, the substrate 2 is divided and the strength of the semiconductor laser element 100 is significantly reduced. Therefore, the height H_{A} of the cavity section 43 is less than the thickness H of the substrate 2. In other words, the height H_{A} of the cavity section 43 is preferably less than the thickness H of the substrate 2 and is one tenth or greater, and the height H_{A} of the cavity section 43 is more preferably one third or greater of the thickness H of the substrate 2.

In addition, in a case where the cavity section 43 is formed by laser scribing, a coating film 27 (see FIG. 3) containing a metal and/or a metal oxide is formed on an inner wall of the cavity section 43 by using a laser having a pulse width on the order of nanoseconds. Ga is an example of the metal contained in the coating film 27. Further, Ga₂O₃ is an example of the metal oxide contained in the coating film 27. In the present embodiment, the n-side electrode 24 and the pad electrode 25 are formed after the cavity section 43 is formed, but the cavity section 43 may be formed by laser scribing after the n-side electrode 24 and the pad electrode 25 are formed. In this case, the coating film 27 contains a metal such as Ti or Au, and/or a metal oxide such as Ga₂O₃ or Ti₂.

Further, by changing a sweep speed of a laser pulse having a pulse width on the order of nanoseconds at a repetition frequency of several tens of kHz, the width of the cavity section 43 can be changed periodically. As a result, a recessed and protruding portion (recessed portion 45 and protruding portion 46) having a periodic wavy shape can be formed in a longitudinal direction (Y direction) on a side wall of the cavity section 43. The cavity section 43′ in which the side wall of the cavity section 43 is provided with the recessed and protruding portion is indicated by a reference numeral 402 in FIG. 4. Instead of the recessed and protruding portion, one or more recessed portions 45 or one or more protruding portions 46 may be formed on the side wall of the cavity section 43.

Subsequently, in step S9, debris generated by forming the chip dividing groove 42 and the cavity section 43 by laser scribing is removed (debris removing step). The debris is attached to the lower surface of the substrate 2 along the chip dividing groove 42 and the cavity section 43, and is mainly composed of group III metal such as Ga, Al, or In.

The debris removing step is performed by, for example, wet etching. Specifically, the wafer 50 is immersed in an acid or alkaline etchant to dissolve and remove the debris. The etchant is not particularly limited to a specific etchant, and examples thereof include the etchant containing an acid such as nitric acid, sulfuric acid, hydrochloric acid, or phosphoric acid, or the etchant containing an alkali such as sodium hydroxide or potassium hydroxide. In a case where the etchant may corrode the p-side upper layer electrode 23 and the like, the wafer 50 may be immersed in the etchant after that portion is covered with a resist or the like.

Debris may be removed by dry etching using a chlorine based gas (SiCl₄, Cl₂, or the like), Ar gas, or the like.

Subsequently, in step S10, the n-side electrode 24 is formed on the lower surface of the substrate 2 by vacuum vapor deposition or sputtering (n-side electrode forming step).

When the n-side electrode 24 such as the above-mentioned single layer of Ti or Ti/Al multilayer body is formed on the lower surface of the substrate 2, the metal film 24A of Ti, Al, or Ga is also formed on the inner wall of the cavity section 43 (see FIG. 3). When the n-side electrode 24 is formed, heat treatment is performed to reduce contact resistance between the substrate 2 and the n-side electrode 24 and ensure ohmic contact.

Subsequently, in step S11, the pad electrode 25 is formed on the n-side electrode 24 by vacuum vapor deposition or sputtering (pad electrode forming step). When the pad electrode 25 made of Au or the like described above is formed on the n-side electrode 24, the metal film 25A made of Au is also formed on the inner wall of the cavity section 43 (see FIG. 3).

In the present embodiment, the metal film 24A and the metal film 25A are formed in accordance with the formation of the n-side electrode 24 and the pad electrode 25, but the metal films may be formed separately from the formation of the n-side electrode 24 and the pad electrode 25. Further, either one of the metal films 24A and 25A may be formed on the inner wall of the cavity section 43.

Subsequently, in step S12, a plurality of bar dividing grooves 41 are formed by a diamond point in the semiconductor layer 10 of the wafer 50 (bar dividing groove forming step) (see FIG. 10). The bar dividing groove 41 is formed at one end portion of the substrate 2 in the X direction, extends in the X direction orthogonal to the ridge portion 30, and is disposed between the p-side upper layer electrodes 23.

By forming the bar dividing grooves 41 only at one end portion of the substrate 2, it is possible to reduce workloads compared to a case of forming the bar dividing grooves 41 on the entire wafer 50. In the first cutting step described below, the wafer 50 is divided at the bar dividing groove 41, and the side walls of the bar dividing groove 41 form the emission surface 1A and the opposing surface 1B of the semiconductor laser element 100 (see FIG. 4). Thus, the distance between the bar dividing grooves 41 is a resonator length of the waveguide 31 of the semiconductor laser element 100 (see FIG. 4), and the resonator length is formed to be approximately 600 μm, for example.

The bar dividing groove 41 may be formed by laser scribing. In this case, the debris removing step of step S9 is more preferably performed after the bar dividing groove forming step of step S12.

Subsequently, in step S13, the wafer 50 is cleaved by applying a blade into each bar dividing groove 41, to form a plurality of bars 51 that are bar-shaped intermediates (first cutting step). In this step, as described above, a resonator end face of the waveguide 31 is formed by a cleavage surface.

In the first cutting step, when cleavage occurs from the bar dividing groove 41 in the upper surface of the wafer 50 toward the cavity section 43 in the lower surface, the resonator end face is not formed flat. Thus, the cavity section 43 is formed at a position that does not overlap with the bar dividing groove 41. When the cavity section 43 is separated from the bar dividing groove 41 by 10 μm or greater in the longitudinal direction of the ridge portion 30, the wafer 50 can be reliably cleaved from the bar dividing groove 41 in a direction perpendicular to the lower surface of the semiconductor laser element 100. As a result, when the semiconductor laser element 100 is diced, the cavity section 43 separates from the end face of the waveguide 31 by 10 μm or greater in the longitudinal direction of the waveguide 31.

Subsequently, in step S14, the end face coating film 26 is formed on the resonator end faces, which are both ends of the bar 51, by vacuum vapor deposition or sputtering (end face coating film forming step) (see FIG. 11). The end face coating film 26 on the emission surface 1A is formed of the low reflective film, and the end face coating film 26 on the opposing surface 1B is formed of the highly reflective film. As a result, light can be efficiently emitted from the emitting portion 31A (see FIG. 1), and the surfaces of both end faces can be protected.

Subsequently, in step S15, the bar 51 is cleaved by applying a blade into each chip dividing groove 42 and is diced into a plurality of chips (second cutting step). As a result, the semiconductor laser element 100 illustrated in FIG. 1 is obtained.

### Summary of First Embodiment

The semiconductor laser element 100 that emits laser light according to a first aspect of the disclosure includes the substrate 2 and the semiconductor layer 10 provided on the substrate 2. The semiconductor layer 10 includes the waveguide 31 that extends in the Y direction (predetermined direction) and emits laser light from the emission surface 1A (one end face). The substrate 2 includes the plurality of cavity sections 43 intersecting the Y direction and extending, and the plurality of cavity sections 43 are provided in the substrate 2 such that at least parts of at least two cavity sections 43 of the plurality of cavity sections 43 overlap with each other along the Y direction. The length W_{A} of each of the plurality of cavity sections 43 in the direction perpendicular to the Y direction (X direction) is shorter than the length W of the semiconductor laser element 100 in the X direction.

According to the above configuration, since the cavity sections 43 are formed in the substrate 2, the stray light incident on the substrate 2 from the waveguide 31 is shielded, and the stray light leaking from the substrate 2 can be reduced. Further, the length W_{A} of each of the cavity sections 43 is shorter than the length W. As a result, it is possible to reduce the possibility that the semiconductor laser element 100 cracks at a position other than the desired cleavage surface.

In the semiconductor laser element 100 according to a second aspect of the disclosure, in the first aspect, the cavity sections 43 may overlap with each other so that any one cavity section 43 of the plurality of cavity sections 43 exists across the entirety of the semiconductor laser element 100 in the X direction.

According to the above configuration, when viewed from the emission surface 1A of the semiconductor laser element 100, the cavity sections 43 can be disposed in a wider area in the substrate 2. As a result, in the semiconductor laser element 100, stray light leaking from the substrate 2 can be more effectively reduced.

In the semiconductor laser element 100 according to a third aspect of the disclosure, in the above-described first or second aspect, at least one cavity section 43 of the plurality of cavity sections 43 may be the groove including the opening on the lower surface of the substrate 2.

According to the above configuration, in a case where the groove including the opening on the lower surface of the substrate 2 is formed as the cavity section 43 for reducing stray light leaking from the substrate 2, the cavity section 43 can be easily formed by laser scribing or the like.

In the semiconductor laser element 100 according to a fourth aspect of the disclosure, in the third aspect, the height H_{A} (groove depth) of the cavity section 43 may be one third or greater of the height H of the substrate 2 (thickness of the substrate 2).

According to the above configuration, stray light leaking from the substrate 2 can be reduced more effectively.

In the semiconductor laser element 100 according to a fifth aspect of the disclosure, in the third or fourth aspect, the metal film 24A and/or 25A may be disposed on the inner wall of the cavity section 43, which is the groove.

According to the above configuration, since the metal film 24A and/or 25A is disposed on the inner wall of the cavity section 43, which is the groove, the stray light can be reflected by the metal film 24A and/or 25A. As a result, the stray light leaking from the substrate 2 can be further reduced.

In the semiconductor laser element 100 according to a sixth aspect of the disclosure, in the fifth aspect, the coating film 27 containing at least one of the metal or the metal oxide may be provided between the inner wall of the cavity section 43, which is the groove, and the metal film 24A.

According to the above configuration, since the coating film 27 containing the metal and/or the metal oxide is provided on the inner wall of the cavity section 43, the adhesion strength of the n-side electrode 24 to the substrate 2 can be improved.

In the semiconductor laser element 100 according to a seventh aspect of the disclosure, in any of the above third to sixth aspects, at least the recessed portion 45 or the protruding portion 46 may be provided on the side wall of the cavity section 43.

According to the above configuration, since the recessed portion 45 and/or the protruding portion 46 is provided on the side wall of the cavity section 43, the stray light that has entered the cavity section 43 from the substrate 2 can be diffusely reflected, and the stray light leaking from the substrate 2 can be further reduced.

In the semiconductor laser element 100 according to an eighth aspect of the disclosure, in any one of the above first to seventh aspects, at least a part of at least one cavity section 43 of the plurality of cavity sections 43 may be inclined with respect to the X direction when the semiconductor laser element 100 is viewed from the upper surface side. Specific examples of the eighth aspect of the disclosure will be described in detail in other fourth to ninth embodiments below.

According to the above configuration, since the cavity section 43 is inclined with respect to the X direction, the stray light can be reflected in a direction different from the emission direction of the laser light (a direction parallel to the waveguide 31). As a result, the stray light leaking from the substrate 2 can be further reduced.

In the semiconductor laser element 100 according to a ninth aspect of the disclosure, in any one of the above first to eighth aspects, each of the plurality of cavity sections 43 may be provided inside the substrate 2 when the semiconductor laser element 100 is viewed from the upper surface side.

According to the above configuration, since the cavity sections 43 are not in contact with the end portion of the semiconductor laser element 100 in the X direction, the strength of the semiconductor laser element 100 can be increased and the possibility of element cracking can be further reduced. Note that a specific example of the ninth aspect of the disclosure will be described in detail in other third to sixth embodiments below.

In the semiconductor laser element 100 according to a tenth aspect of the disclosure, in any one of the above first to ninth aspects, the length W_{A} of each of the plurality of cavity sections 43 in the X direction may be 80% or less of the length W of the semiconductor laser element 100 in the X direction.

According to the above configuration, the possibility of element cracking of the semiconductor laser element 100 can be further reduced.

In the semiconductor laser element 100 according to an eleventh aspect of the disclosure, in any one of the above first to tenth aspects, the plurality of cavity sections 43 may be provided at the distance of 10 μm or greater from the emission surface 1A along the Y direction.

The method for manufacturing the semiconductor laser element 100 of the present embodiment includes the step of cleaving the wafer to obtain the bar, and the step of cleaving the bar to obtain the semiconductor laser element 100. In the step of cleaving the bar, in a case where the emission surface 1A and the cavity section 43 are close to each other, the cleavage surface may not be formed flat, and may cause division failure. The cavity section 43 is provided at the distance of 10 μm or greater from the emission surface 1A, thereby reducing the possibility of causing the division failure.

However, as illustrated in FIGS. 4 and 5, the plurality of cavity sections 43 may be formed at positions closer to the emission surface 1A than the opposing surface 1B. For example, all of the plurality of cavity sections 43 may be provided closer to the emission surface 1A than a center of the semiconductor laser element 100 in the Y direction. In this case, the stray light leaking from the substrate 2 can be efficiently reduced.

Hereinafter, other embodiments of the disclosure will be described. Note that, for convenience of explanation, components having the same function as those described in the above-described embodiment will be denoted by the same reference signs, and descriptions of those components will be omitted.

### Second Embodiment

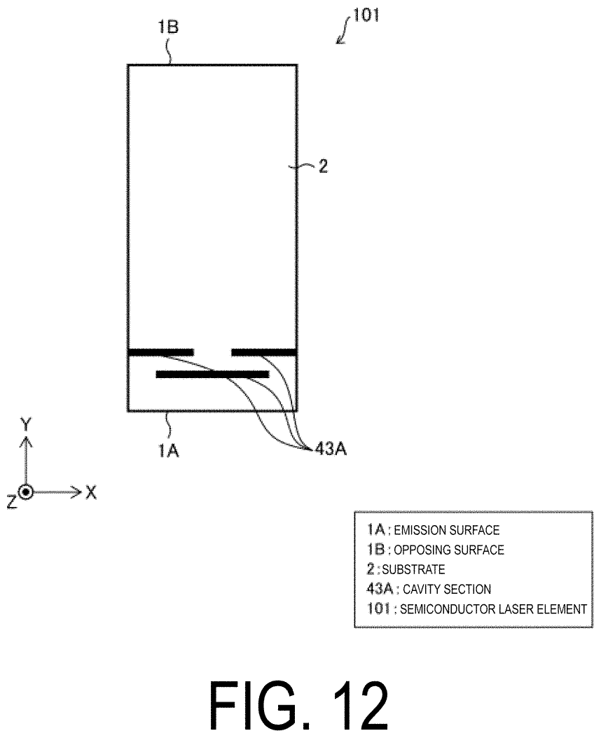

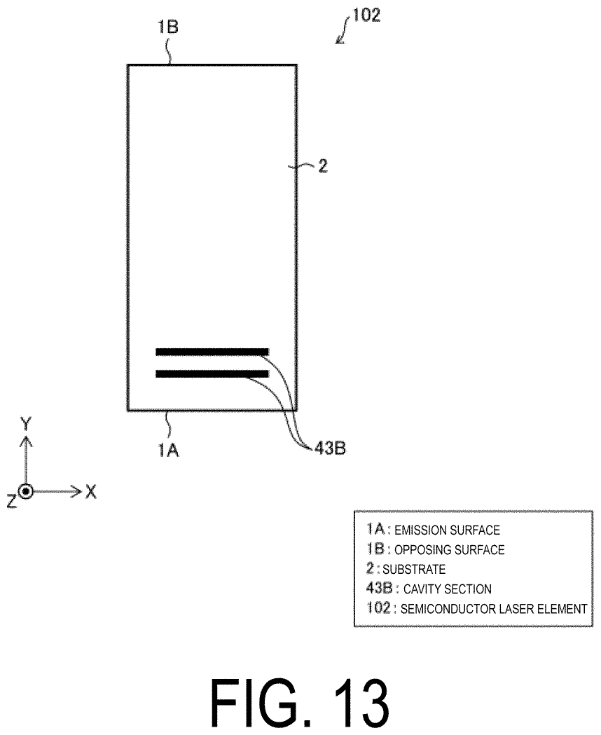

Hereinafter, a second embodiment of the disclosure will be described with reference to FIG. 12. FIG. 12 is a diagram illustrating a forming pattern of cavity sections 43A of a semiconductor laser element 101 according to the second embodiment of the disclosure. Note that FIG. 12 is a bottom view of the substrate 2 of the semiconductor laser element 101, and members other than the substrate 2 and the cavity sections 43A are omitted for clarity. This also applies to FIGS. 13 to 19.

In the semiconductor laser element 101 according to the second embodiment, the forming pattern (shape and arrangement pattern) of the cavity sections 43A is different from the forming pattern of the cavity sections 43 of the semiconductor laser element 100 according to the first embodiment.

Specifically, as illustrated in FIG. 12, the semiconductor laser element 101 is different from that in the first embodiment in that two cavity sections 43A of three cavity sections 43A are formed at the same distance from the emission surface 1A. One end of one cavity section 43A of the two cavity sections 43A is in contact with one side surface of the substrate 2, and one end portion of another cavity section 43A is in contact with another side surface of the substrate 2. Further, each of the two cavity sections 43A, in a part thereof, overlaps with still another cavity section 43A (the cavity section 43A formed closer to the emission surface 1A) along the Y direction.

The three cavity sections 43A extend in a direction intersecting the Y direction in the semiconductor laser element 101. Further, parts of the two cavity sections 43A overlap with each other so that any one of the three cavity sections 43A exists across the entire X direction of the substrate 2 when viewed from the emission surface 1A side. Further, a length W_{A} of each of the cavity sections 43A in the X direction is shorter than a length W of the semiconductor laser element 101 in the X direction.

According to the above configuration, since the plurality of cavity sections 43A are provided across the entire X direction of the substrate 2 when viewed from the emission surface 1A side, in the semiconductor laser element 101, stray light can be effectively reduced as in the first embodiment. Further, in the semiconductor laser element 101, when the semiconductor laser element 101 is viewed from the upper surface side, one of the plurality of cavity sections 43A is provided inside the substrate 2. Thus, in the semiconductor laser element 101, the possibility of element cracking at a position other than a desired cleavage surface can be reduced.

Note that FIG. 12 is a diagram schematically illustrating a part of the configuration of the semiconductor laser element 101 according to the present embodiment, and does not limit the dimensions of the members. This also applies to other embodiments.

### Third Embodiment

Hereinafter, a third embodiment of the present disclosure will be described with reference to FIG. 13. FIG. 13 is a diagram illustrating a forming pattern of cavity sections 43B of a semiconductor laser element 102 according to the third embodiment of the disclosure. The cavity section 43B of the semiconductor laser element 102 according to the present embodiment differs from those in the first and second embodiments in that both end portions of each of the cavity sections 43B in the X direction are not in contact with both end portions of the semiconductor laser element 102 in the X direction.

Specifically, the semiconductor laser element 102 according to the third embodiment includes two cavity sections 43B. The two cavity sections 43B each extend in a direction intersecting the Y direction and overlap with each other along the Y direction. In addition, each of the two cavity sections 43B is not in contact with both end portions of the semiconductor laser element 102 in the X direction. In other words, each of the two cavity sections 43B is provided inside the substrate 2 when the semiconductor laser element 102 is viewed from the upper surface side. Further, the two cavity sections 43B have the same length W_{A} in the X direction, and all portions thereof overlap with each other along the Y direction.

According to the above configuration, since the semiconductor laser element 102 according to the third embodiment is provided with the two cavity sections 43 overlapping along the Y direction, stray light leaking from the substrate 2 can be reduced. Additionally, since each of the cavity sections 43B is not in contact with the side surface of the substrate 2 (the end portion of the semiconductor laser element 102 in the X direction), strength of the semiconductor laser element 102 is increased as compared to those in the first and second embodiments, and the possibility of element cracking can be further reduced.

### Fourth Embodiment

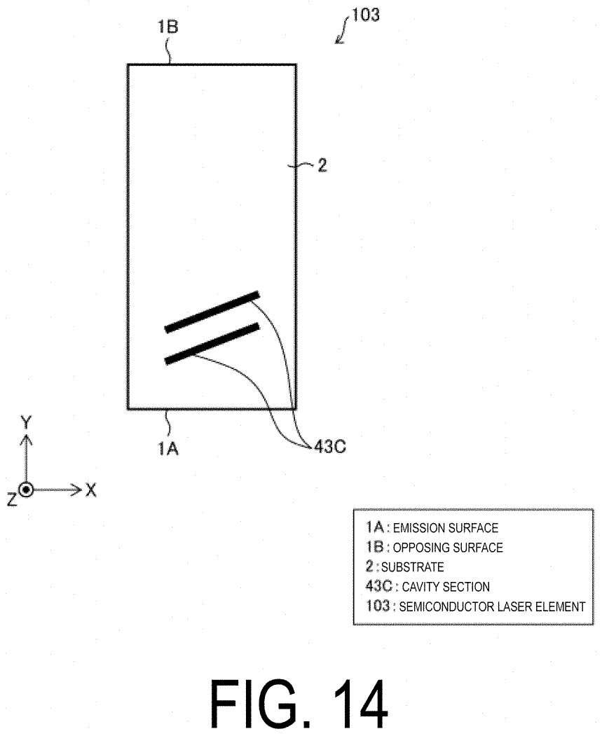

Hereinafter, a fourth embodiment of the present disclosure will be described with reference to FIG. 14. FIG. 14 is a diagram illustrating a forming pattern of cavity sections 43C of a semiconductor laser element 103 according to the fourth embodiment of the disclosure. The cavity section 43C of the semiconductor laser element 103 according to the present embodiment differs from that in the third embodiment in that the cavity section 43C is inclined with respect to the X direction.

Specifically, the semiconductor laser element 103 according to the fourth embodiment includes two cavity sections 43C. The two cavity sections 43C each extend in a direction intersecting the Y direction and overlap with each other along the Y direction. Further, each of the two cavity sections 43C has a linear shape when viewed from the upper surface side of the substrate 2, and is inclined with respect to the X direction. Furthermore, each of the two cavity sections 43C is not in contact with both end portions of the semiconductor laser element 102 in the X direction. Additionally, the two cavity sections 43C have the same length W_{A} in the X direction (length when viewed from the emission surface 1A side), and all the portions thereof overlap with each other along the Y direction.

According to the above configuration, similar to the third embodiment, in the semiconductor laser element 103 according to the fourth embodiment, the possibility of element cracking can be further reduced. Additionally, since the cavity section 43C is inclined with respect to the X direction, stray light can be reflected in a direction different from an emission direction of laser light. As a result, the stray light leaking from the substrate 2 can be further reduced as compared to the third embodiment.

### Fifth Embodiment

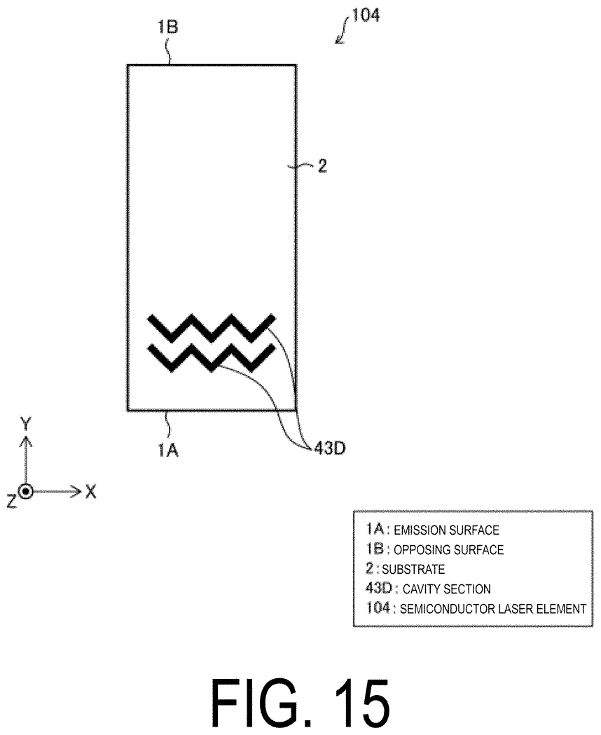

Hereinafter, a fifth embodiment of the present disclosure will be described with reference to FIG. 15. FIG. 15 is a diagram illustrating a forming pattern of cavity sections 43D of a semiconductor laser element 104 according to the fifth embodiment of the disclosure. The cavity section 43D of the semiconductor laser element 104 according to the present embodiment differs from that in the third embodiment in that the cavity section 43D has a zigzag shape.

Specifically, the semiconductor laser element 104 according to the fifth embodiment includes two cavity sections 43D. The two cavity sections 43D each extend in a direction intersecting the Y direction and overlap with each other along the Y direction. The two cavity sections 43D each have a zigzag shape. The zigzag shape is, in other words, a combination of portions having different inclinations with respect to the X direction. The angle of inclination may be different in each portion of the cavity section 43D, and the cavity section 43D may include a portion substantially parallel to the X direction (angle≈0°). Further, each of the two cavity sections 43D is not in contact with both end portions of the semiconductor laser element 104 in the X direction. Furthermore, the two cavity sections 43D have the same length W_{A} in the X direction (length when viewed from the emission surface 1A side), and all the portions thereof overlap with each other along the Y direction.

According to the above configuration, similar to the fourth embodiment, in the semiconductor laser element 104 according to the fifth embodiment, the possibility of element cracking can be further reduced. In addition, since each portion of the cavity section 43D is inclined with respect to the X direction, stray light can be reflected in directions different from the emission direction of laser light. As a result, as in the fourth embodiment, the stray light leaking from the substrate 2 can be further reduced.

### Sixth Embodiment

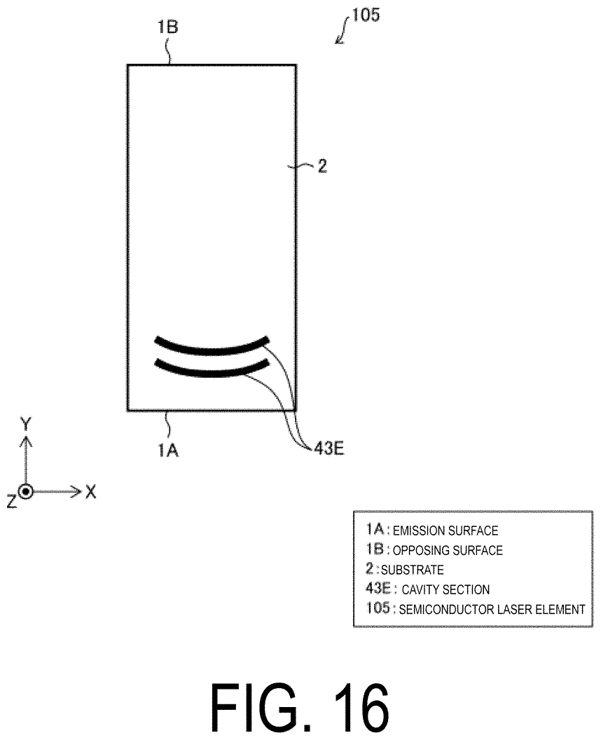

Hereinafter, a sixth embodiment of the present disclosure will be described with reference to FIG. 16. FIG. 16 is a diagram illustrating a forming pattern of cavity sections 43E of a semiconductor laser element 105 according to the sixth embodiment of the disclosure. The cavity section 43E of the semiconductor laser element 105 according to the present embodiment differs from that in the third embodiment in that the cavity section 43E has a curved shape.

Specifically, the semiconductor laser element 105 according to the sixth embodiment includes two cavity sections 43E. The two cavity sections 43E each extend in a direction intersecting the Y direction and overlap with each other along the Y direction. The two cavity sections 43E each have a curved shape. A tangent at any point of the cavity section 43E intersects the Y direction. Further, the tangent is inclined with respect to the X direction. That is, the curved shape can be said to be a combination of portions having different inclinations with respect to the X direction. The angle of the inclination may be different in each portion of the cavity section 43E, and the cavity section 43E may include a portion substantially parallel to the X direction. Further, each of the two cavity sections 43E is not in contact with both end portions of the semiconductor laser element 105 in the X direction. Furthermore, the two cavity sections 43E have the same length W_{A} in the X direction (length when viewed from the emission surface 1A side), and all the portions thereof overlap with each other along the Y direction.

According to the above configuration, similar to the fourth embodiment, in the semiconductor laser element 105 according to the sixth embodiment, the possibility of element cracking can be reduced. Additionally, since the direction of the tangent at any point of the cavity section 43E is inclined with respect to the X direction, the stray light can be reflected in directions different from the emission direction of laser light. As a result, as in the fourth embodiment, the stray light leaking from the substrate 2 can be further reduced.

### Seventh Embodiment

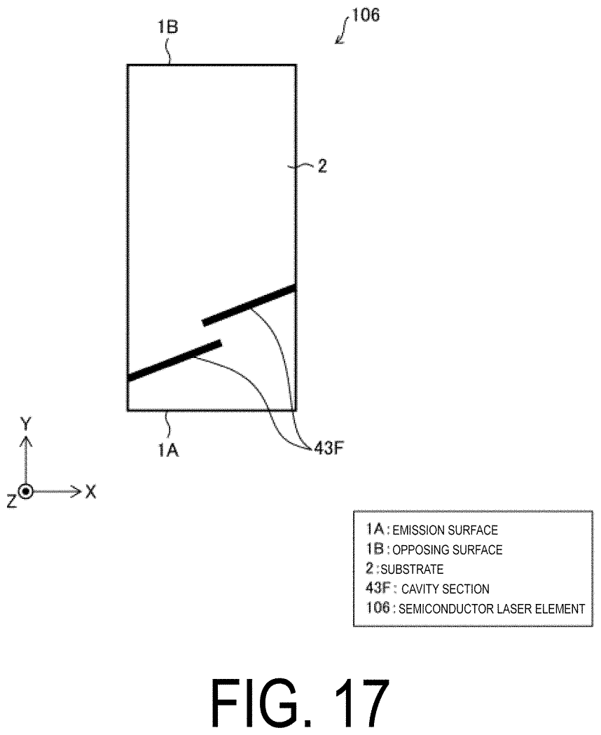

Hereinafter, a seventh embodiment of the present disclosure will be described with reference to FIG. 17. FIG. 17 is a diagram illustrating a forming pattern of cavity sections 43F of a semiconductor laser element 106 according to the seventh embodiment of the disclosure. The cavity section 43F of the semiconductor laser element 106 according to the present embodiment differs from that in the fourth embodiment in that one end portion of each of the cavity sections 43F in the X direction is in contact with the side surface of the substrate 2.

Specifically, the semiconductor laser element 106 according to the seventh embodiment includes two cavity sections 43F. The two cavity sections 43F each extend in a direction intersecting the Y direction. Further, parts of the two cavity sections 43F overlap with each other such that at least one cavity section 43F exists across the entire X direction of the substrate 2 when viewed from the emission surface 1A side.

According to the above configuration, in the semiconductor laser element 106 according to seventh embodiment, stray light leaking from the substrate 2 can be more effectively reduced as compared to the fourth embodiment. In addition, since one end portion of the two cavity sections 43F is not in contact with the side surface, in the semiconductor laser element 106, the possibility of element cracking can be reduced.

### Eighth Embodiment

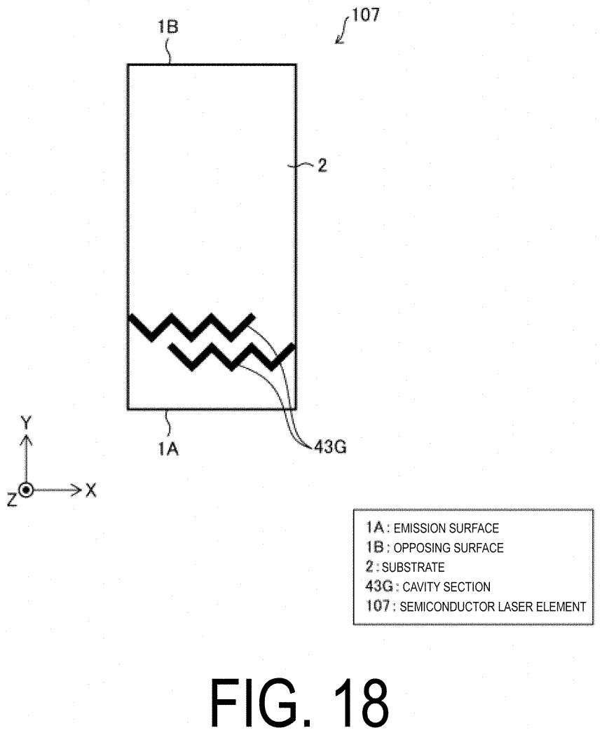

Hereinafter, an eighth embodiment of the present disclosure will be described with reference to FIG. 18. FIG. 18 is a diagram illustrating a forming pattern of cavity sections 43G of a semiconductor laser element 107 according to the eighth embodiment of the disclosure. The cavity section 43G of the semiconductor laser element 107 according to the present embodiment differs from that in the fifth embodiment in that one end portion of each of the cavity sections 43G in the X direction is in contact with the side surface of the substrate 2.

Specifically, the semiconductor laser element 107 according to the eighth embodiment includes two cavity sections 43G. A description of the zigzag shape of the cavity section 43G is the same as that of the fifth embodiment. The two cavity sections 43G each extend in a direction intersecting the Y direction. In addition, parts of the two cavity sections 43G overlap with each other such that at least one cavity section 43G exists across the entire X direction of the substrate 2 when viewed from the emission surface 1A side.

According to the above configuration, in the semiconductor laser element 107 according to the eighth embodiment, stray light leaking from the substrate 2 can be more effectively reduced compared to the fifth embodiment. In addition, since one end portion of the two cavity sections 43G is not in contact with the side surface, in the semiconductor laser element 107, the possibility of element cracking can be reduced.

### Ninth Embodiment

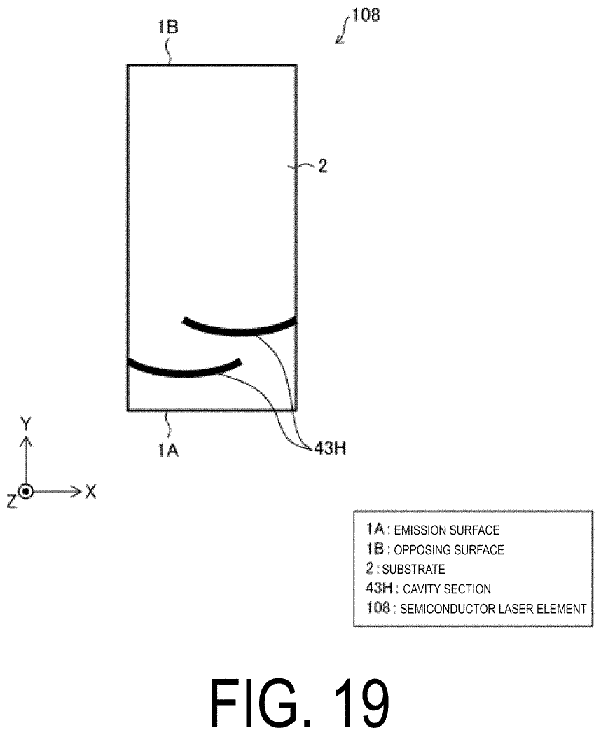

Hereinafter, a ninth embodiment of the present disclosure will be described with reference to FIG. 19. FIG. 19 is a diagram illustrating a forming pattern of cavity sections 43H of a semiconductor laser element 108 according to the ninth embodiment of the disclosure. The cavity section 43H of the semiconductor laser element 108 according to the present embodiment differs from that in the sixth embodiment in that one end portion of each of the cavity sections 43H in the X direction is in contact with the side surface of the substrate 2.

Specifically, the semiconductor laser element 108 according to the ninth embodiment includes two cavity sections 43H. A description of the curved shape of the cavity section 43H is the same as that of the sixth embodiment. Further, parts of the two cavity sections 43H overlap with each other such that at least one cavity section 43H exists across the entire X direction of the substrate 2 when viewed from the emission surface 1A side.

According to the above configuration, in the semiconductor laser element 108 according to the ninth embodiment, stray light leaking from the substrate 2 can be more effectively reduced compared to the sixth embodiment. In addition, since one end portion of the two cavity sections 43H is not in contact with the side surface, in the semiconductor laser element 108, the possibility of element cracking can be reduced.

### Tenth Embodiment

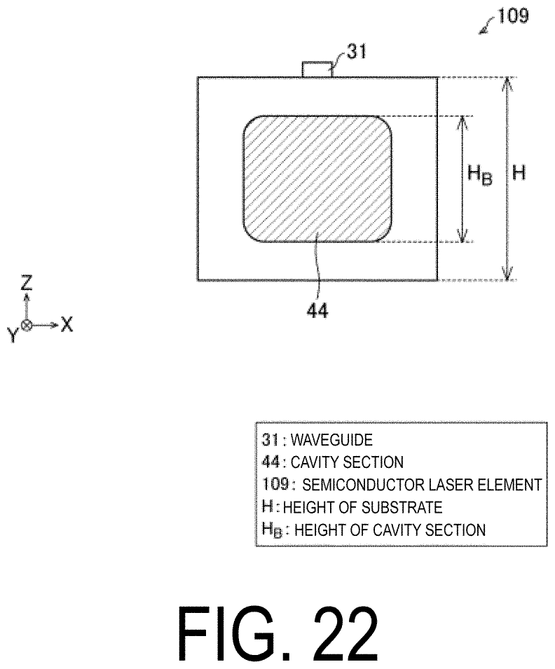

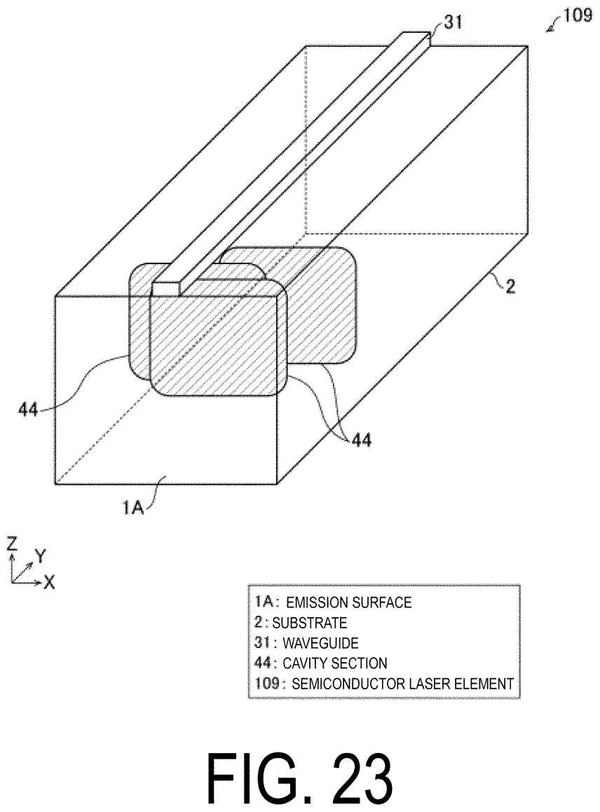

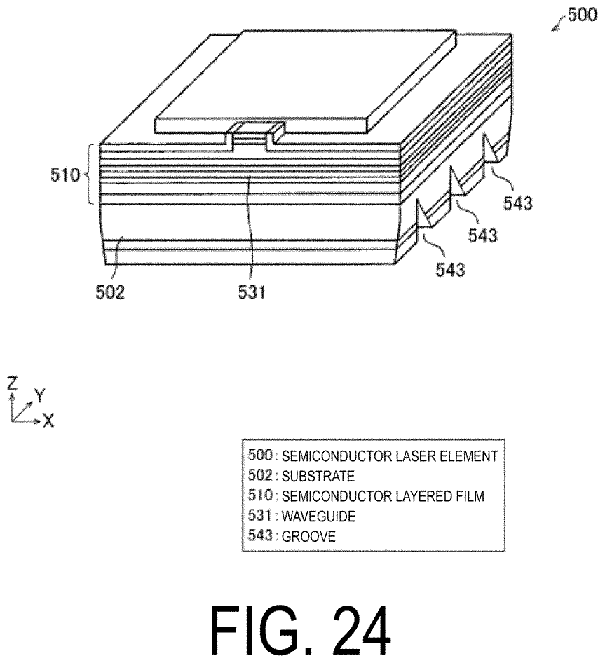

Hereinafter, a tenth embodiment of the present disclosure will be described with reference to FIGS. 22 and 23. FIG. 22 is a schematic front view illustrating a structure of a cavity section 44 of a semiconductor laser element 109 according to the tenth embodiment when viewed from the emission surface 1A. FIG. 23 is a schematic perspective view illustrating a structure of a plurality of cavity sections 44 of the semiconductor laser element 109 according to the tenth embodiment.

The cavity section 44 of the semiconductor laser element 109 according to the present embodiment differs from that in the first embodiment in that the cavity section 44 is formed inside the substrate 2 without including an opening on the lower surface of the substrate 2. In other words, it can be said that the cavity section 44 is a cavity provided in the substrate 2. The cavity section 44 is formed in the substrate 2 by, for example, stealth dicing with a laser.

Note that in FIGS. 22 and 23, the forming pattern of the cavity sections 44 is similar to that of the first embodiment, but is not limited to this forming pattern. The forming pattern of the cavity sections 44 may be, for example, a pattern similar to any of the second to ninth embodiments. For example, as in the first embodiment, a part of the cavity section 44 may be in contact with the side surface of the substrate 2. The embodiment is not limited to this, a part of the cavity section 44 may be in contact with the upper surface of the substrate 2. In other words, the cavity section 44 may be provided at least separated from the lower surface of the substrate 2.

Further, it is not always necessary that all the plurality of cavity sections formed in the substrate 2 be the cavity sections 44. Some of the cavity sections formed in the substrate 2 may be the cavity section 44, and another cavity section may be, for example, at least one of the cavity sections 43, 43D, or 43E.

### Summary of Tenth Embodiment

In the semiconductor laser element 109 according to a twelfth aspect of the disclosure, in the above first or second aspect, at least one cavity section 44 of the plurality of cavity sections 44 is provided at least separated from the lower surface of the substrate 2.

According to the above configuration, the cavity section 44 as a cavity is separated from the lower surface of the substrate 2. In this case as well, similar to the case in which the plurality of cavity sections 43, which are the grooves, are provided in the substrate 2, stray light leaking from the substrate 2 can be reduced. Additionally, since the cavity section 44 does not include an opening on the lower surface of the substrate 2, the possibility of element cracking of the semiconductor laser element 109 can be further reduced.

Further, in the semiconductor laser element 109 according to a thirteenth aspect of the disclosure, in the above twelfth aspect, a height He (length in the thickness direction of the substrate) of the cavity section 44, which is the cavity, may be one third or greater of the height H of the substrate 2 (thickness of the substrate).

According to the above configuration, stray light leaking from the substrate 2 can be reduced more effectively.

Further, in the semiconductor laser element 109 according to a fourteenth aspect of the disclosure, at least a recessed portion or a protruding portion may be provided on an inner wall of the cavity section 44, which is the cavity, in the above twelfth or thirteenth aspect.

According to the above configuration, since the recessed portion and/or the protruding portion is provided on the inner wall of the cavity section 44, stray light that has entered the cavity section 44 from the substrate 2 can be diffusely reflected, and stray light leaking from the substrate 2 can be further reduced.

Further, in the semiconductor laser element 109 according to a fifteenth aspect of the disclosure, in any one of the above twelfth to fourteenth aspects, each of the plurality of cavity sections 44, which are the cavities, may be provided inside the substrate 2 when the semiconductor laser element 109 is viewed from the upper surface side.

According to the above configuration, since the cavity section 44, which is the cavity, is not in contact with the end portion of the semiconductor laser element 109 in the X direction, the cavity section 44 includes no opening on any of the upper surface, the side surface, and the lower surface (bottom surface) of the substrate 2. As a result, the strength of the semiconductor laser element 109 is increased, and the possibility of element cracking can be further reduced.

Further, in the semiconductor laser element 109 according to a sixteenth aspect of the disclosure, in any one of the above twelfth to fifteenth aspects, the length W_{A} of each of the plurality of cavity sections 44, which are the cavities, in the X direction may be 80% or less of the length W of the semiconductor laser element 100 in the X direction.

According to the above configuration, the possibility of element cracking of the semiconductor laser element 109 can be further reduced.

Further, in the semiconductor laser element 109 according to a seventeenth aspect of the disclosure, in any one of the above twelfth to sixteenth aspects, the plurality of cavity sections 44, which are the cavities, may be provided at a distance of 10 μm or greater from the emission surface 1A along the Y direction.

The cavity sections 44 are provided at the distance of 10 μm or greater from the emission surface 1A, thereby reducing the possibility of causing the division failure.

### Results of Verification Test

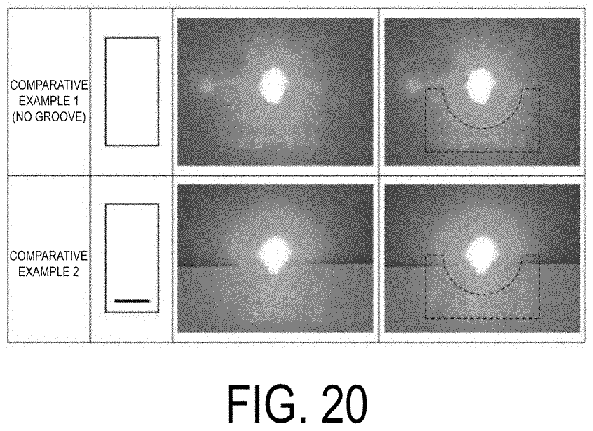

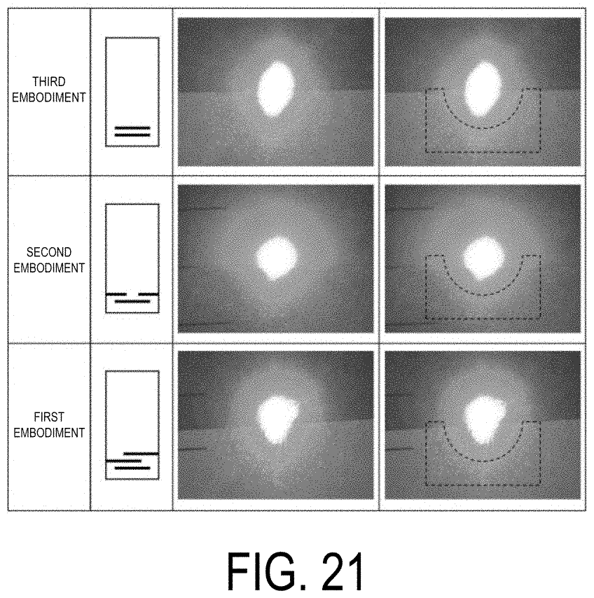

Here, a test conducted to confirm effect of representative semiconductor laser elements (semiconductor laser elements 100, 101, and 102) according to one aspect of the disclosure will be described with reference to FIGS. 20 and 21.

In this test, as comparative examples, a semiconductor laser element in which no cavity section (groove) was formed (Comparative Example 1) and a semiconductor laser element including one cavity section (groove) (Comparative Example 2) were used. As the representative examples of the semiconductor laser element according to the one aspect of the disclosure, the semiconductor laser elements (semiconductor laser elements 100, 101, and 102) according to the first to third embodiments were used. With the two comparative examples and the three semiconductor laser elements according to the one aspect of the disclosure, a state in which laser light was actually emitted was photographed from the emission surface 1A side, and stray light leaking from the substrate 2 was examined.

FIG. 20 is a diagram illustrating test results for the comparative examples. FIG. 21 is a diagram illustrating test results for the semiconductor laser elements according to the one aspect of the disclosure.

As illustrated in FIG. 20, in the comparative examples, it is possible to visually recognize how stray light is leaking in an area of the substrate 2 surrounded by a broken line. As illustrated in FIG. 21, in the semiconductor laser elements 100 to 102 of the first to third embodiments according to the one aspect of the disclosure, in an area of the substrate 2 surrounded by a broken line, it is possible to visually recognize how stray light leaking from the substrate 2 is reduced as compared to Comparative Examples 1 and 2. That is, this test demonstrated that in the semiconductor laser elements according to one aspect of the disclosure represented by the semiconductor laser elements 100, 101, and 102, stray light leaking from the substrate 2 can be reduced. In other words, this test demonstrated that by providing the substrate 2 with a plurality of cavity sections overlapping along the Y direction, stray light leaking from the substrate 2 can be reduced as compared to the case in which the cavity section is not provided in the substrate 2 or only one cavity section is provided in the substrate 2.

Further, this test demonstrated that in the semiconductor laser elements 100 and 101 of the first and second embodiments, stray light leaking from the substrate 2 can be further reduced as compared to the semiconductor laser element 102 of the third embodiment. In other words, it was demonstrated that stray light leaking from the substrate 2 can be reduced by forming a plurality of cavity sections such that at least one of a plurality of cavity sections exists across the entire X direction of the substrate 2 when viewed from the emission surface 1A side.

### Supplementary Information

The disclosure is not limited to each of the above-described embodiments. It is possible to make various modifications within the scope of the claims. An embodiment obtained by appropriately combining technical elements each disclosed in different embodiments falls also within the technical scope of the disclosure. Furthermore, technical elements disclosed in the respective embodiments may be combined to provide a new technical feature.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A semiconductor laser element configured to emit laser light, the semiconductor laser element comprising:
a substrate; and
a semiconductor layer provided on the substrate,
wherein the semiconductor layer includes a waveguide extending in a predetermined direction and configured to emit the laser light from one end face of the waveguide,
the substrate includes a plurality of cavity sections intersecting the predetermined direction and extending,
the plurality of cavity sections are provided in the substrate such that at least parts of at least two cavity sections of the plurality of cavity sections overlap with each other along the predetermined direction, and
a length of each of the plurality of cavity sections in a direction perpendicular to the predetermined direction is shorter than a length of the semiconductor laser element in the perpendicular direction.

2. The semiconductor laser element according to claim 1,
wherein at least parts of the at least two cavity sections overlap with each other such that any one cavity section of the plurality of cavity sections exists across the entirety of the semiconductor laser element in the perpendicular direction.

3. The semiconductor laser element according to claim 1,
wherein at least one cavity section of the plurality of cavity sections is a groove including an opening on a lower surface of the substrate.

4. The semiconductor laser element according to claim 3,
wherein a depth of the groove is one third or greater of a thickness of the substrate.

5. The semiconductor laser element according to claim 3,
wherein a metal film is disposed on an inner wall of the groove.

6. The semiconductor laser element according to claim 5,
wherein a coating film containing at least one of a metal or a metal oxide is provided between the inner wall of the groove and the metal film.

7. The semiconductor laser element according to claim 3,
wherein at least a recessed portion or a protruding portion is provided on a side wall of the groove.

8. The semiconductor laser element according to claim 1,
wherein at least one cavity section of the plurality of cavity sections is separated from at least a lower surface of the substrate.

9. The semiconductor laser element according to claim 8,
wherein a length of each of the plurality of cavity sections in a thickness direction of the substrate is one third or greater of a thickness of the substrate.

10. The semiconductor laser element according to claim 8,
wherein at least a recessed portion or a protruding portion is provided on an inner wall of each of the plurality of cavity sections.

11. The semiconductor laser element according to claim 1,
wherein at least a part of at least one cavity section of the plurality of cavity sections is inclined with respect to the perpendicular direction in a case where the semiconductor laser element is viewed from an upper surface side.

12. The semiconductor laser element according to claim 1,
wherein each of the plurality of cavity sections is provided inside the substrate in a case where the semiconductor laser element is viewed from an upper surface side.

13. The semiconductor laser element according to claim 1,
wherein a length of each of the plurality of cavity sections in the perpendicular direction is 80% or less of a length of the semiconductor laser element in the perpendicular direction.

14. The semiconductor laser element according to claim 1,
wherein the plurality of cavity sections are provided at a distance of 10 μm or greater from the one end face along the predetermined direction.
